(19) United States
(12) Patent Application Publication
(10) Pub. No.: US 2005/0286232 A1
(43) Pub. Date: Dec. 29, 2005

(54) Heat sink

(75) Inventors: Chun-Chi Chen, Tu-Cheng (TW); Shi-Wen Zhou, Shenzhen (CN); Shin-Hsuu Wung, Tu-Cheng (TW); Zhan Wu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology Co., Ltd., Tu-Cheng City (TW)

(21) Appl. No.: 11/135,164

(22) Filed: May 23, 2005

(30) Foreign Application Priority Data
Jun. 25, 2004 (CN) 200420071121.7

(51) Int. Cl. H05K 7/20

(52) U.S. Cl. 361/710; 165/80.3

(57) ABSTRACT

A heat sink includes a base and a plurality of spaced parallel fins arranged on the base. Adjacent fins define a plurality of passages there between. Each passage includes an inlet and at least one outlet. The base and the fins made separately, and the fins is thin, such that amount of the fins arranged on the base increases. And the fins are disposed on the base alternately or/and staggered such that the inlet and the outlet are wider than a middle part of the passage to lower airflow resistance thereat. Thus, the heat sink has large heat dissipating area and low airflow resistance synchronously.

### BACKGROUND

1. Field of the Invention

The present invention relates generally to heat sinks, and more particularly to a heat sink used for heat generating electronic components.

2. Prior Art

It is acknowledged that electronic components such as central processing units (CPUs) generate amounts of heat during operation. With advancement of computer technology, the ability of electronic components is upgraded rapidly. Accordingly, more and more heat is generated. In order to dissipate the heat generated by the electronic components, numerous heat dissipation devices are applied. Generally, a heat dissipation device comprises a heat sink. And in order to provide forced convection airflow to the heat sink, a fan is often attached to the heat sink. The heat sink comprises a first surface in close contact with the electronic component, for absorbing heat generated by the electronic component, and a second surface forming a plurality of spaced fins, for dissipating the heat transferred from the first surface. A plurality of passages, each of which has an inlet and an outlet at two ends thereof respectively, are defined between adjacent fins, for airflow from the fan passing therethrough.

Generally, in order to increase heat dissipating area of the heat sink, amount of the fins increases. However, what is brought out therefore, is that total thickness of the fins increases. As a result, the inlets and outlets of the passages become narrow, thereby increasing airflow resistance between the adjacent fins, and thus, heat dissipating efficiency of the heat sink decreases. So, the conventional heat sink can not has large heat dissipating area and low airflow resistance synchronously.

### SUMMARY

Accordingly, what is needed is to provide a heat sink having large heat dissipating area and low airflow resistance.

A heat sink of a preferred embodiment of the present invention comprises a base and a plurality of spaced parallel fins arranged on the base. Adjacent fins define a plurality of passages therebetween. Each passage comprises an inlet and at least one outlet. The base and the fins made separately, and the fins is thin, such that amount of the fins arranged on the base increases. And the fins are disposed on the base alternately or/and staggered such that the inlet and the outlet are wider than a middle part of the passage to lower airflow resistance thereat. Thus, the heat sink has large heat dissipating area and low airflow resistance synchronously.

Other advantages and novel features of the present invention will become more apparent from the following detailed description when taken in conjunction with the accompanying drawings, in which:

### BRIEF DESCRIPTION OF THE DRAWINGS

FIG. 1 is an exploded isometric view illustrating a heat sink according to a first embodiment of the present invention and relative components;

FIG. 2 is an assembled isometric view of FIG. 1; and

FIG. 3 is an isometric view of a heat sink according to a second embodiment of the present invention.

FIG. 4 is an isometric view of a heat sink according to a third embodiment of the present invention.

FIG. 5 is an isometric view of a heat sink according to a forth embodiment of the present invention.

### DETAILED DESCRIPTION OF THE EMBODIMENTS

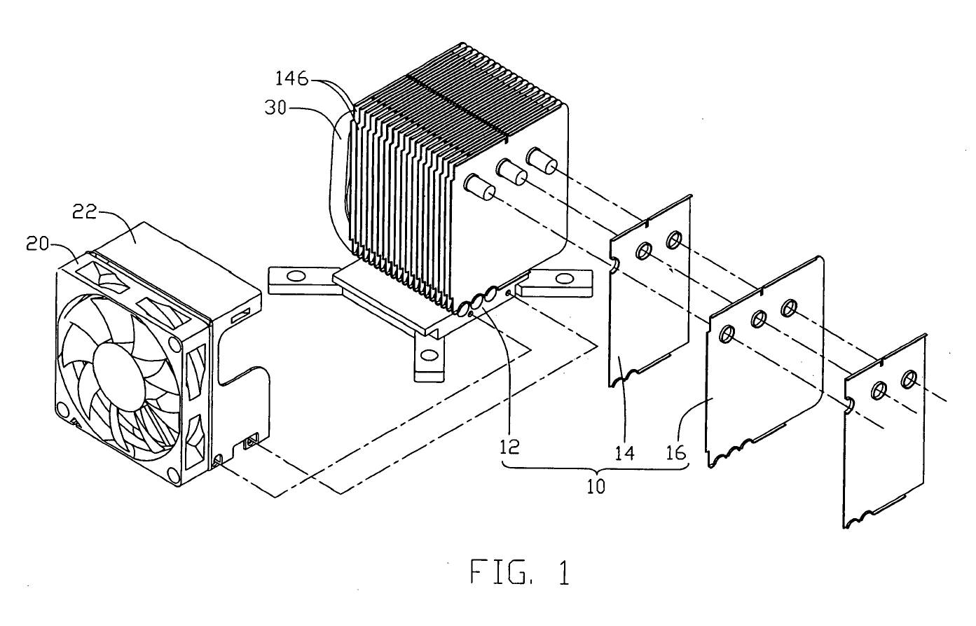

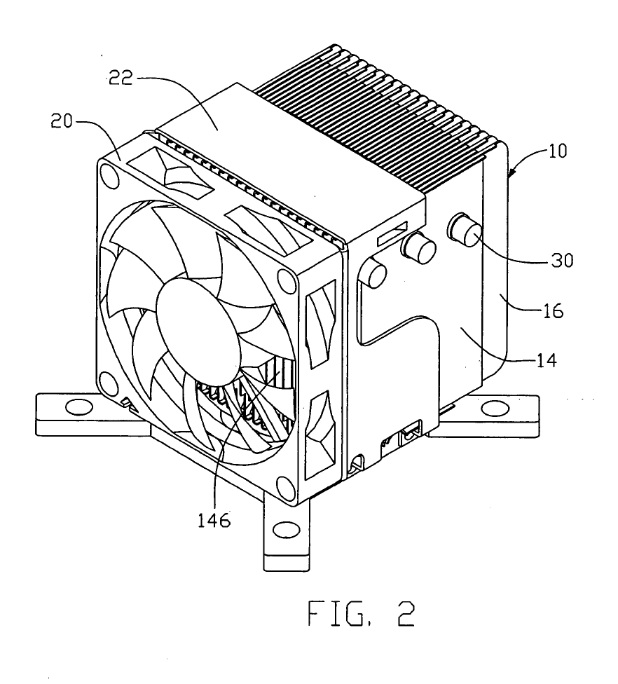

Referring to FIG. 1 and FIG. 2, a heat sink 10 of a heat dissipation device according to a first embodiment of the present invention is shown. The heat sink 10 is secured on a heat source like a CPU (not shown) mounted on a printed circuit board (not shown). A fan 20 is fastened on a side of the heat sink 10 by a bracket 22. Three U-shape heat pipes 30 connect two opposite portions of the heat sink 10 by two parallel section thereof, for accelerating heat transfer from the portion close to the CPU to the other portion of the heat sink 10.

The heat sink 10 comprises a base 12 for contacting the CUP to absorb heat generated by it, and a plurality of parallel and spaced fins arranged on the base 12. The base 12 and the fins are made separately, and the fins are arranged on the base 12 by welding or adhering or other means. The fins comprise a plurality of first fins 14 and second fins 16. The first fins 14 are uniform with the second fins 16 in height, while the width of them is different. Such as, each first fin 14 is shorter than each second fin 16. The first fins 14 and second fins 16 are disposed alternately. Therefore, two ends of the second fins 16 project beyond the first fins 14. Thus, a plurality of passages 146, each of which has an inlet and an outlet defined respectively at two opposite ports thereof for airflow passing through, are defined between the adjacent first fins 14 and second fins 16. The inlet and the outlet are larger than middle part of the passage 146.

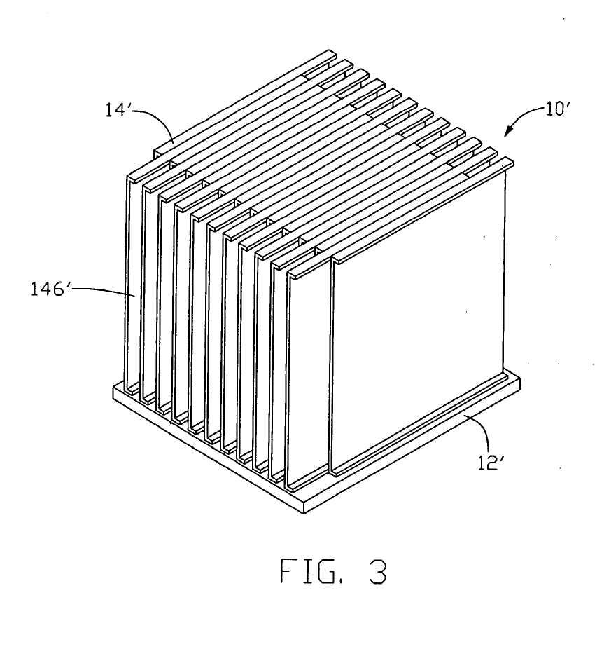

Referring to FIG. 3, a heat sink 10′ according to a second embodiment of the present invention, comprises a plurality of parallel and uniform fins 14′ arranged on a base 12′. The adjacent fins 14′ are staggered with one another, such that one end of each fin 14′ project laterally beyond the adjacent one. Accordingly, an inlet and an outlet defined respectively at two opposite ports of each passage 146′ defined between the adjacent fins 14′, are wider than a middle part of the passage 146′.

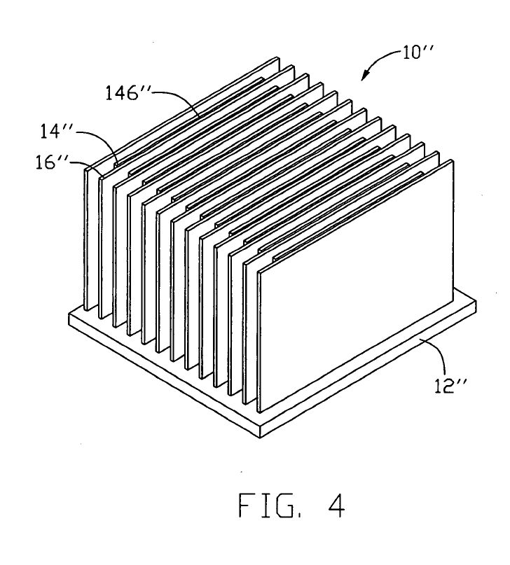

Referring to FIG. 4, a heat sink 10″ according to a third embodiment of the present invention, comprises a plurality of parallel fins attached on the base 12″. The fins comprise a plurality of first fins 14″ and second fins 16″. The first fin 14″ is different from the second fin 16″ in height and width. According to FIG. 4, both the height and width of the first fin 14″ are smaller than those of the second fin 16″. The first fins 14″ and second fins 16″ are disposed alternately. As a result, an upper end and two lateral ends of the second fins 16″ project beyond the first fins 14″.

According to the third embodiment of the present invention, as a replacement, the width of the first fin 14″ is smaller than that of the second fin 16″, while the height of the first fin 14″ is larger than that of the second fin 16″.

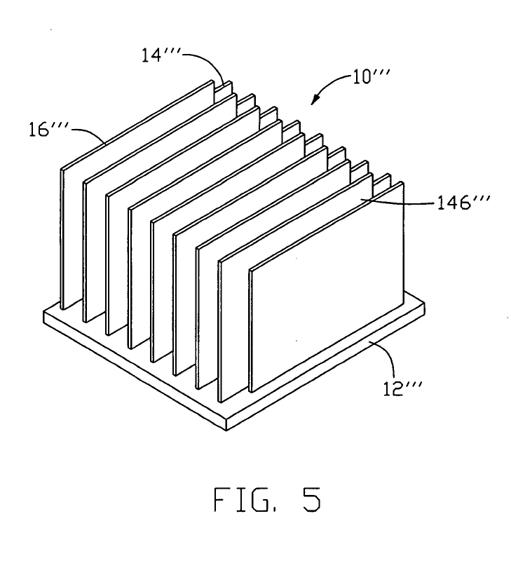

Referring to FIG. 5, a heat sink 10′″ according to a forth embodiment of the present invention, comprises a plurality of parallel fins arranged on the base 12′″. The fins comprise a plurality of first fins 14′″ and a plurality of second fins 16′″. Each first fin 14′″ is different from each second fin 16′″ in height, but uniform with each second fin 16′″ in width. The first fins 14′″ and the second fins 16′″ are disposed alternately and staggered with one another, such that one lateral end of the adjacent first fin 14′″ and second fin 16′″ projects laterally beyond the adjacent one, and an upper end of the second fin 16′″ projects upwardly beyond the first fin 14′″.

According to the third and the forth embodiments, the fan 20 (not shown) can be located above the heat sink 10″/10′″. Accordingly, an inlet, defined at top port, and two outlets, defined at two lateral ports of each passage 146″/146′″, are wider than a middle part of each passage 146″/146′″ defined between the adjacent first fin 14″/14′″ and second fin 16″/16′″.

In the present invention, the base and the fins are made separately, so the fins can be made thin, such that amount of the fins arranged on the base increases, that is to say, the heat dissipating area of the heat sink is enlarged. And the fins are disposed on the base alternately or/and staggered, such that the inlet and the outlet are wider than the middle part of each passage, thereby decreasing the airflow resistance thereat. Thus, the heat sink has large heat dissipating area and low airflow resistance synchronously. Accordingly, heat dissipation efficiency of the heat sink is improved.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat sink comprising:
a base; and
a plurality of spaced parallel fins arranged on the base, adjacent fins defining a plurality of passages therebetween, each passage comprising an inlet and at least one outlet;
wherein, the base and the fins are made separately, whereby the fins is thin and amount of the fins arranged on the base increases, the fins are disposed on the base alternately or/and staggered such that the inlet and the outlet are wider than a middle part of the passage.

2. The heat sink of claim 1, wherein the fins comprise a plurality of first fins and second fins disposed alternately with the first fins.

3. The heat sink of claim 2, wherein the first fins and the second fins are uniform in width, but different in height.

4. The heat sink of claim 3, wherein the first fins and the second fins are staggered with one anther such that one lateral end of each first fin and each second fin projects laterally relative to the adjacent one.

5. The heat sink of claim 4, wherein the inlet and the outlets are defined at top port and two lateral ports of the passage respectively.

6. The heat sink of claim 2, wherein the first fins and the second fins are different in length, two lateral ends of the second fins project beyond the first fins.

7. The heat sink of claim 6, wherein the inlet and the outlet are defined at two lateral ports of the passage respectively.

8. The heat sink of claim 7, wherein a fan is located at a side of the heat sink.

9. The heat sink of claim 6, wherein the first fins and the second fins are different in height, upper ends of the second fins project upwardly beyond the first fins.

10. The heat sink of claim 9, wherein the inlet and the outlets are defined respectively at top and lateral ports of the passage.

11. The heat sink of claim 1, wherein the adjacent fins are uniform and disposed staggered with one anther such that an end of each of the adjacent fins projects laterally beyond the other one of the adjacent fins.

12. The heat sink of claim 11, wherein the inlet and the outlet are defined at two lateral ports of the passage respectively.

13. A heat dissipation device comprising:
a heat sink, comprising a base and a plurality of spaced parallel fins arranged on the base, adjacent fins defining a plurality of passages there between, each passage comprising an inlet and at least one outlet;
at least one heat pipe, connecting two opposite portions of the heat sink for transferring heat form one of the portions to another one of the portions of the heat sink; and
a fan, attached to the heat sink correspondingly with the passages, for providing forced convection airflow in the heat sink;
wherein, the base and the fins are made separately, whereby the fins is thin and amount of the fins arranged on the base increases, the fins are disposed on the base alternately or/and staggered such that the inlet and the outlet are wider than a middle part of the passage.

14. A heat dissipation device comprising:
a base for being thermally contactable with a heat source to gain heat therefrom; and
a plurality of fins arranged next to said base and thermally contactable therewith to gain said heat therefrom, each fin of said plurality of fins being completely spaced from adjacent fins of said plurality of fins so as to define corresponding passages between said each fin and said adjacent fins, each passage comprising an inlet to accept cooler airflow for heat dissipation and an outlet to release said airflow carrying said heat from said each fin and said adjacent fins, at least one of said inlet and said outlet being enlarged by means of arrangement of said plurality of fins.

15. The heat dissipation device of claim 14, wherein said inlet and said outlet commonly communicate with at least two passages respectively.

16. The heat dissipation device of claim 14, wherein said inlet is definable beside one of a first side of said each fin of said plurality of fins extending parallel with said base, and a second side of said each fin extending perpendicular to said base.

17. The heat dissipation device of claim 14, wherein said plurality of fins comprises first fins, and second fins sized different from said first fins in at least one of width thereof and height thereof.

18. The heat dissipation device of claim 17, wherein said first fins and said second fins are arranged in at least one of an alternate way and a staggered way.

19. The heat dissipation device of claim 14, wherein said plurality of fins are identically sized and arranged in a staggered way.

20. The heat dissipation device of claim 14, further comprising at least one heat pipe used to thermally contact with at least two portions of said each fin of said plurality of fins.
